(19) United States
(12) Patent Application Publication
(10) Pub. No.: US 2010/0102390 A1
(43) Pub. Date: Apr. 29, 2010

(54) Gated diode with increased voltage tolerance

(75) Inventors: Vladislav Vashchenko, Palo Alto, CA (US); Konstantin G. Korablev, Sunnyvale, CA (US)

Correspondence Address: Vollrath & Associates, #531, 588 Sutter St., San Francisco, CA, 94102, US

(73) Assignee: National Semiconductor Corporation

(21) Appl. No.: 12/290,060

(22) Filed: Oct. 27, 2008

(51) Int. Cl. H01L 29/00; H01L 21/336

(52) U.S. Cl. 257/355; 438/294; 257/E29.001

(57) ABSTRACT

In a gated diode ESD protection structure, the gate is biased to a voltage higher than ground and gate size is reduced while ensuring adequate spacing between p+ and n+ regions of the diode by blocking at least one of n-lightly doped region and p-lightly doped region.

### FIELD OF THE INVENTION

The invention relates to Electrostatic Discharge (ESD) protection devices. In particular it relates to gated diode based ESD protection devices.

### BACKGROUND OF THE INVENTION

In a quest for faster and smaller footprint ESD protection devices for I/O pins, gated diodes as illustrated in FIG. 1 are being used instead of conventional composite diodes. The conventional composite diode of FIG. 1 includes a p+ region 100 separated from an n+ region 102, which are formed in a composite and are separated by a shallow trench isolation region 104, which in this case is 0.28 um in length.

The gate diode also includes a p+ region and an n+ region but in this case the p+ and n+ regions are spaced apart by a diffusion region over which there is a gate. TCAD simulations and TLP measurements have shown definite advantages of gated diodes over composite diodes, including improved forward recovery and ESD current. However, lower reverse breakdown and reverse leakage is a concern in gated diodes.

The present invention seeks to address this problem by providing a gated diode with higher voltage tolerance.

### SUMMARY OF THE INVENTION

According to the invention there is provided a gated diode ESD protection structure, comprising a p+ region and an n+ region spaced from each other to define a diffusion region between them, and a gate formed over the diffusion region, the gate including a gate contact for providing a gate bias voltage to the gate. The p+ region and n+ region may be formed in a substrate or well.

Further according to the invention there is provided a method of improving parameters of a gated diode that includes a p+ region and an n+ region spaced from each other to define a diffusion region between them, and a gate formed over the diffusion region, the method comprising applying a gate bias voltage to the gate. The method may include forming at least one of an n-lightly doped region in which the n+ region is formed, and a p-lightly doped region in which the p+ region is formed. The method may also include reducing gate length in order to improve forward current characteristics. One or both of the n-lightly doped region and p-lightly doped region may be blocked to provide greater n+ region to p+ region spacing and thereby reduce reverse leakage current without having to increase gate length.

Still further, according to the invention, there is provided a method of implementing a gated diode that includes a p+ region and an n+ region formed in a composite and spaced from each other to define a diffusion region between them, and a gate formed over the diffusion region, the method comprising forming only one or none of the p+ region and n+ region in a lightly doped region while blocking the formation of at least one of the lightly doped regions.

### BRIEF DESCRIPTION OF THE DRAWINGS

FIG. 1 is a cross-section through a prior art composite diode,

FIG. 2 is a cross-section through one embodiment of a gated diode of the invention,

FIG. 3 shows simulation data in the form of forward current density-voltage curves for various prior art gated diodes compared to a prior art composite diode,

FIG. 4 shows TLP measured data in the form of pulsed current versus pulsed voltage curves for various prior art gated diodes compared to a prior art composite diode,

FIG. 5 shows breakdown characteristics for a prior art composite diode compared to two prior art gated diodes, and

FIG. 6 shows forward breakdown characteristics for two gated diodes with gates biased in accordance with the invention compared to a prior art unbiased gated diode.

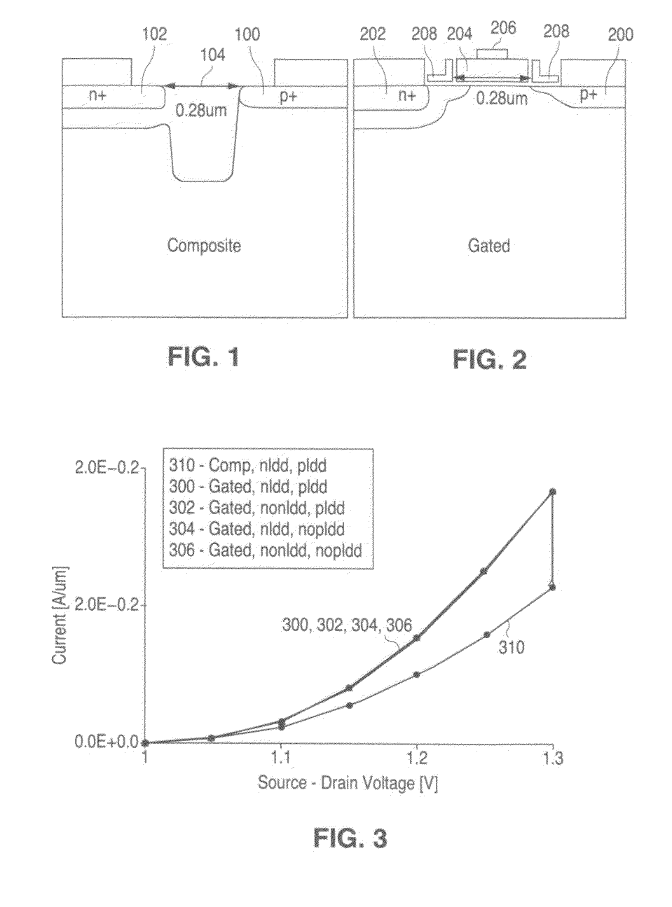

### DETAILED DESCRIPTION OF THE INVENTION

One embodiment of a gated diode of the invention is shown in FIG. 2. It includes a p+ region 200 and an n+ region 202 but that are spaced apart by a diffusion region over which there is a gate 204 with gate contact 206. Nitride spacers 208 are formed on either side of the gate 204. In order to form the p+ region 200 and n+ region 202 a self-alignment process is adopted in which the gate 204 acts as a mask during the formation of the n+ and p+ regions. In order to limit lateral diffusion a lightly doped region is typically first formed in such a process so that the n+ region 202 is formed in an n-lightly doped region, while the p+ region 200 is formed in a p-lightly doped region. However, as is discussed in greater detail below simulation results show that the lightly doped regions detrimentally impact the reverse breakdown. The present invention therefore proposes eliminating one or both of the lightly doped regions by blocking the formation of the lightly doped regions under the nitride spacers using a mask. In the FIG. 2 embodiment for instance, both of the lightly doped regions have been blocked. However, it will be appreciated that only one of the lightly doped regions could be eliminated from the structure.

As discussed above, forward current is substantially improved in gated diodes over composited diodes, however reverse breakdown and reverse leakage is a concern. Therefore, keeping the p+ and n+ regions of the diode further apart is a benefit. However, as will also be shown below, simulation results indicate that as the gate size is increased, the forward current parameters get worse. Thus the alternative of reducing gate size to improve forward current has to be weighed against the increased leakage current and reduced reverse breakdown under small gate sizes. This highlights the advantage of the one aspect of the invention. By keeping gate size smaller but keeping the p+ and n+ regions further apart through the blocking of one or both lightly doped regions, the benefit of a small gate size and sufficient spacing between n+ and p+ regions can be realized.

As part of another aspect of the invention, the present invention proposes a gated diode with increased voltage tolerance by providing the gate with a gate contact and biasing the gate.

FIG. 3, shows current density versus source-drain voltage (voltage over the p+ and n+ regions) simulation data for various gated diodes compared to a composite diode. As evident from FIG. 3 the gated diodes (curves 300, 302, 304, 306) have a 60% forward current improvement at 1.3V compared to the composite diode (curve 310). The curves 300, 302, 304, 306 have different lightly doped (LDD) configurations by providing for blocking of one or both of the n and p LDDs. However, as is discussed below, the forward current is not materially affected by these different LDD blockings.

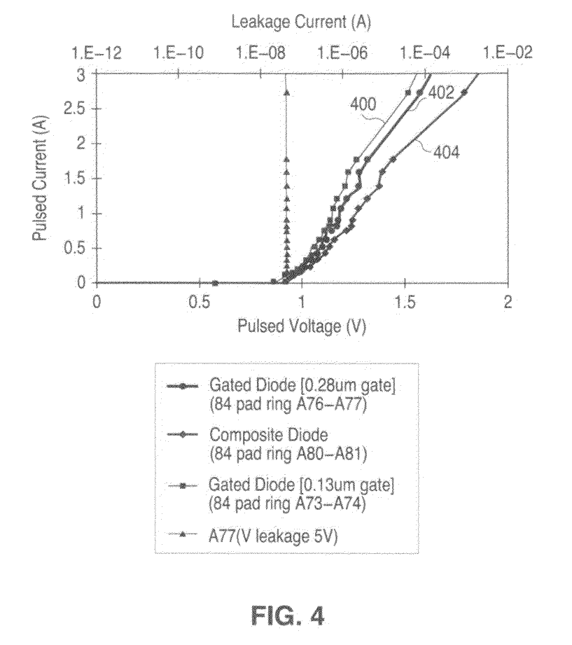

These forward current effects are also borne out by TLP measurement data as shown in FIG. 4, which shows forward pulsed current versus pulsed voltage curves for two gated diodes (curve 400 with a 0.13 um gate length, and curve 402 with a 0.28 um gate length) compared to a composite diode (curve 404). FIG. 4 shows a 40% increase in forward current for gated diodes over conventional composite diodes. These results were found to be true in gated diodes whether or not they included a p-lightly doped region or an n-lightly doped region.

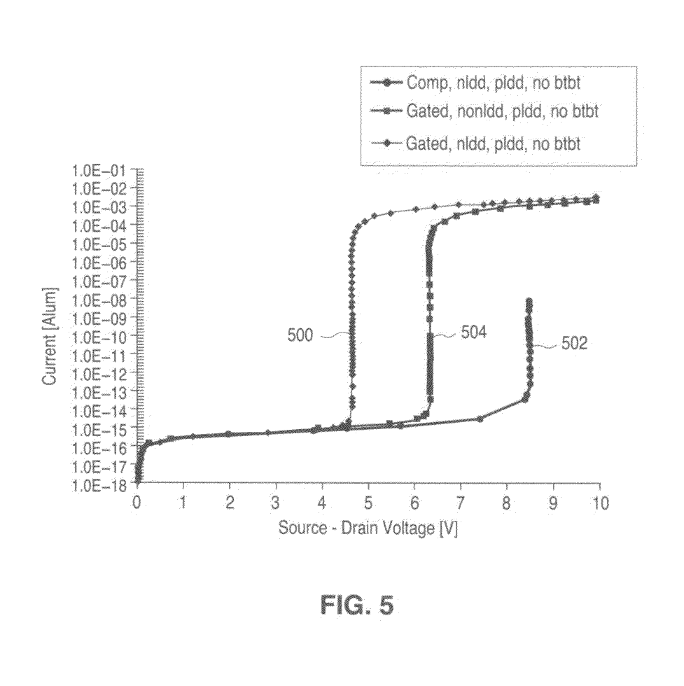

Nevertheless, these gated diodes have their own drawbacks, in the form of reduced breakdown voltage and increased reverse leakage compared to composite diodes. The reduced reverse breakdown can be seen in the simulation results shown in FIG. 5. The pre-breakdown reverse leakage is seen to be similar in gated diodes and composite diodes, however the breakdown voltage of the gated diode (curve 500) was found to be about 4V lower at about 4.5V) compared to that of the composite diode (curve 502) which had a breakdown voltage of about 8.5 V.

It was, however, found that the breakdown voltage could be increased to acceptable limits by blocking the lightly doped (LDD) implants (in this case curve 504 shows the results for no n-lightly doped region (NLDD), which provided a breakdown voltage of about 6V). As mentioned above, this was achieved without detrimental results to the forward current capabilities. Also, the pre-breakdown reverse leakage value was found to be comparable in the two types of gated diodes compared to the composite diode.

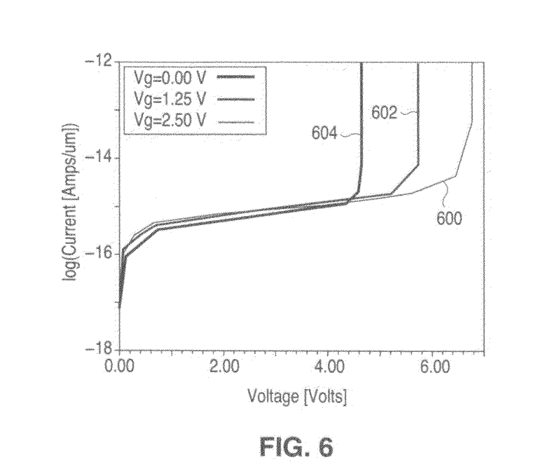

However, one concern with gated diodes is the integrity of the gated oxide, which is effected by hot carriers and the electric field across the gate oxide. In accordance with the invention, in order to alleviate this stress and improve the device lifetime the gate of the gated diode is biased. In one embodiment the gate is biased at half the maximum voltage at the diode terminals. The gate is provided with a contact, which is used to supply the bias voltage to the polysilicon gate. TCAD simulations show that the biasing of the diode gate as proposed by the present invention does not impact the device performance negatively. As shown in FIG. 6, the breakdown voltage increased with increase in the gate voltage. Curve 600 shows the breakdown with a gate voltage of 2.5V, while curve 602 shows the breakdown at a gate voltage of only 1.25 V. Both curve 600 and 602, however show a substantial improvement over the unbiased gate diode shown by curve 604. In addition, the reverse leakage was not affected by the gate voltage.

In order to provide the gate bias, a number of implementations are possible, including a bias circuit (for instance at Vdd of 2.5V) or by using the middle of the diffusion region between the n+ and p+ regions of the diode as a saturation resistor to define a voltage divider. Contact is made to the diffusion region in a conventional way on the side of the device. Instead, a resistive divider can be provided that is connected to Vdd, or the gate of the diode can be implemented as a floating gate electrode instead of connecting the gate to the bulk junction side as in prior art gated diodes.

By making use of gate bias as proposed by the present application, a 2.5V diode can for instance be used as ESD protection structure tolerant for 3.3V circuits.

What is claimed is:

1. A gated diode ESD protection structure, comprising
a p+ region and an n+ region spaced from each other to define a diffusion region between them, and
a gate formed over the diffusion region, the gate including a gate contact for providing a gate bias voltage to the gate.

2. A gated diode of claim 1, wherein the p+ and n+ region are formed in a substrate or well.

3. A method of improving parameters of a gated diode that includes a p+ region and an n+ region spaced from each other to define a diffusion region between them, and a gate formed over the diffusion region, the method comprising applying a gate bias voltage to the gate.

4. A method of claim 3, further comprising forming at least one of an n-lightly doped region in which the n+ region is formed, and a p-lightly doped region in which the p+ region is formed.

5. A method of claim 3, further comprising reducing gate length in order to improve forward current characteristics.

6. A method of claim 4, wherein one or both of the n-lightly doped region and p-lightly doped region are blocked to provide greater spacing between the n+ region and the p+ region.

7. A method of improving parameters of a gated diode that includes a p+ region and an n+ region spaced from each other to define a diffusion region between them, and a gate formed over the diffusion region, the method comprising forming only one or none of the p+ region and n+ region in a lightly doped region while blocking the formation of at least one of the lightly doped regions.

8. A method of claim 8, further comprising biasing the gate to a higher voltage than ground.
